(19) United States
(12) Patent Application Publication
(10) Pub. No.: US 2007/0184188 A1
(43) Pub. Date: Aug. 9, 2007

(54) Method for cleaning a thin film forming apparatus and method for forming a thin film using the same

(76) Inventors: Young-Sun Kim, Yongin-si (KR); Hyeon-Ill Um, Seongnam-si (KR); Hyeon-Su An, Seongnam-si (KR); Young-Suk Jeong, Suwon-si (KR); Hae-Moon Choi, Hwaseong-gun (KR)

Correspondence Address: LEE & MORSE, P.C., 3141 FAIRVIEW PARK DRIVE, SUITE 500, FALLS CHURCH, VA, 22042, US

(21) Appl. No.: 11/702,062

(22) Filed: Feb. 5, 2007

(30) Foreign Application Priority Data
Feb. 7, 2006 (KR) 2006-11850

(51) Int. Cl. B08B 5/04; C23C 16/00

(52) U.S. Cl. 427/248.1; 134/21

(57) ABSTRACT

In a method for a thin film forming apparatus, after the deposition of a thin film is completed, a cleaning gas may be introduced repeatedly into an interior of a process chamber for predetermined intervals. The method may be performed without a drastic temperature drop in the process chamber in order to remove a thin film layer left in the chamber. A purge gas may introduced into the chamber continuously or alternatively with the cleaning gas.

### BACKGROUND OF THE INVENTION

1. Field of the Invention

The present invention disclosed herein relates to a method for operating and maintaining a thin film forming apparatus, and more particularly, to a method for cleaning a thin film forming apparatus using a cleaning gas, and a method for forming a thin film using the same.

2. Description of the Related Art

The semiconductor manufacturing process may include a thin film forming process. Generally, the thin films formed in the manufacturing process of semiconductor devices include insulating thin films, such as a silicon oxide layer and a silicon nitride layer, and conductive thin films, such as a variety of metal thin film, polysilicon thin film, and silicide thin film. Although there are many methods for forming the thin film, physical vapor deposition (PVD), chemical vapor deposition (CVD), and metal-organic CVD (MOCVD) are generally used. For example, in the CVD method, two or more reaction gases are supplied into a process chamber maintained at a predetermined process temperature. Through thermal decomposition and/or chemical reaction of the reaction gases, a reaction product may be deposited, in the form of a thin film, on a surface of a semiconductor wafer in the process chamber. However, the reaction product is also deposited on the inside of the reaction chamber and its internal components, e.g., an inner wall of the chamber and a susceptor which supports the wafer. The unwanted thin film on the susceptor and inside the chamber may reduce the yield of the thin film forming process. The unwanted thin film may contaminate the reaction product formed in the chamber by delaminating from the chamber wall and attaching to the surface of the wafer during subsequent thin film forming processes.

Therefore, the process chamber may be subjected to a cleaning process after a thin film is formed. In a related art, a thin film forming apparatus is cleaned after forming a thin film at a high temperature, e.g., about 500° C. or more. When the temperature of the process chamber drops to a low temperature, e.g., about 300° C. or lower, a cleaning gas and a purge gas may be supplied into the chamber to remove the contaminative reaction product. The cleaning gas and the purge gas are introduced simultaneously and continuously until the cleaning process is finished. This cleaning process may take a long time as the removal rate of the reaction product varies depending on the inner surface shape of the chamber and the location of the reaction product.

Thus, in the related art, after a thin film has been formed at a high temperature, the cleaning process may not be finished before the temperature in the chamber drops to a low temperature. Thus, productivity and the effectiveness of the cleaning process may be diminished.

However, if the cleaning process is performed before the temperature in the chamber drops, another problem may occur. At high temperatures, the cleaning gas may react with the components of the chamber as well as the contaminative reaction products. For example, a heater made of e.g., AlN used for controlling the temperature in the reaction chamber may react with a cleaning gas, e.g., ClF₃ gas to form AlF, which may damage the heater. In addition, the AIF that may delaminate from the heater during the subsequent thin film forming process may attach to the surface of the wafer and contaminate the wafer.

### SUMMARY OF THE INVENTION

The present invention is therefore directed to a method for cleaning a thin film forming apparatus using a cleaning gas and a method for forming a thin film using the same, which substantially overcomes one or more of the problems due to the limitations and disadvantages of the related art.

Embodiments of the present invention provide methods for cleaning a thin film forming apparatus, which include supplying a purge gas in a process chamber of the thin film forming apparatus and periodically supplying a cleaning gas in the process chamber for a predetermined period. The purge gas may also be supplied periodically such that the purge gas and the cleaning gas are supplied in turn. The temperature of the process chamber may be kept at 300° C. or more. In one embodiment, the purge gas is N₂ gas and/or Argon (Ar) gas. Various types of process chambers may benefit from this method, including CVD (Chemical Vapor Deposition) chambers, PVD (Physical Vapor Deposition) chambers, ALD (Atomic Layer Deposition) chambers and others. In one embodiment, the cleaning gas is a fluorine-based gas, such as ClF₃, F₂, CF₄, C₂F₆, NF₃, and SF₆. In one embodiment, the purge gas is supplied while the cleaning gas is not supplied, but the purge gas may be supplied even when the cleaning gas is supplied.

In other embodiments of the present invention, methods for forming a thin film include supplying a first reaction gas and a second reaction gas into a process chamber of a thin film forming apparatus to form the thin film; keeping a supply of the second reaction gas and stopping a supply of the first reaction gas; and supplying periodically the cleaning gas into the process chamber. In one embodiment, the second reaction gas is supplied periodically after the supply of the first reaction gas is stopped. In another embodiment, the second reaction gas and the cleaning gas are supplied in turn. The first reaction gas may be TiCl₄ and the second reaction gas may be N₂. The cleaning gas may be ClF₃, F₂, CF₄, C₂F₆, NF₃, or SF₆. In further embodiments of the present invention, methods for forming a thin film include supplying the first reaction gas through a first supply pipe of the thin film forming apparatus, and supplying the second reaction gas through a second supply pipe of the thin film forming apparatus into a process chamber of the thin film forming apparatus to form a thin film; stopping the supply of the first reaction gas; and periodically supplying the cleaning gas into the process chamber. In one embodiment, the cleaning gas may be supplied through the first supply pipe. The second reaction gas may be supplied periodically after the first reaction gas supply is stopped. In one embodiment, when the first reaction gas supply is stopped, the second reaction gas supply is stopped, and the purge gas is then supplied into the process chamber. In one embodiment, the first reaction gas is TiCl₄ and the second reaction gas is N₂. The cleaning gas is selected from the group comprising ClF₃, F₂, CF₄, C₂F₆, NF₃, and SF₆.

### BRIEF DESCRIPTION OF THE DRAWINGS

The above and other features and advantages of the present invention will become more apparent to those of ordinary skill in the art by describing in detail exemplary embodiments thereof with reference to the attached drawings, in which:

FIG. 1 illustrates a schematic sectional view of a thin film forming apparatus according to an embodiment of the present invention;

FIG. 2 illustrates a schematic view of a method for cleaning a thin film forming apparatus according to an embodiment of the present invention; and

FIG. 3 illustrates a schematic view of a method for cleaning a thin film forming apparatus according to another embodiment of the present invention.

### DETAILED DESCRIPTION OF THE INVENTION

Korean Patent Application No. 2006-11850 filed on Feb. 7, 2006, in the Korean Intellectual Property Office, and entitled: “Method for Cleaning a Thin Film Forming Apparatus and Method for Forming a Thin Film Using the Same,” is incorporated by reference herein in its entirety.

The present invention will now be described more fully hereinafter with reference to the accompanying drawings, in which exemplary embodiments of the invention are illustrated. The invention may, however, be embodied in different forms and should not be construed as limited to the embodiments set forth herein. Rather, these embodiments are provided so that this disclosure will be thorough and complete, and will fully convey the scope of the invention to those skilled in the art.

In the following embodiments, a thin film forming apparatus for forming a metal thin film, such as a titanium nitride layer, in a semiconductor manufacturing process will be described. However, the present invention can be applied to every apparatus that forms an insulating thin film or a conductive thin film in a semiconductor manufacturing process. For example, the invention may be applied to a CVD apparatus, a PVD apparatus, an MOCVD apparatus, an Atomic Layer Chemical Vapor Deposition (ALCVD) apparatus, a diffusion apparatus, a furnace, and the like. Also, the present invention can be applied to every thin film forming apparatus that creates a thin film using a reaction gas, without being limited to the manufacture of semiconductor devices.

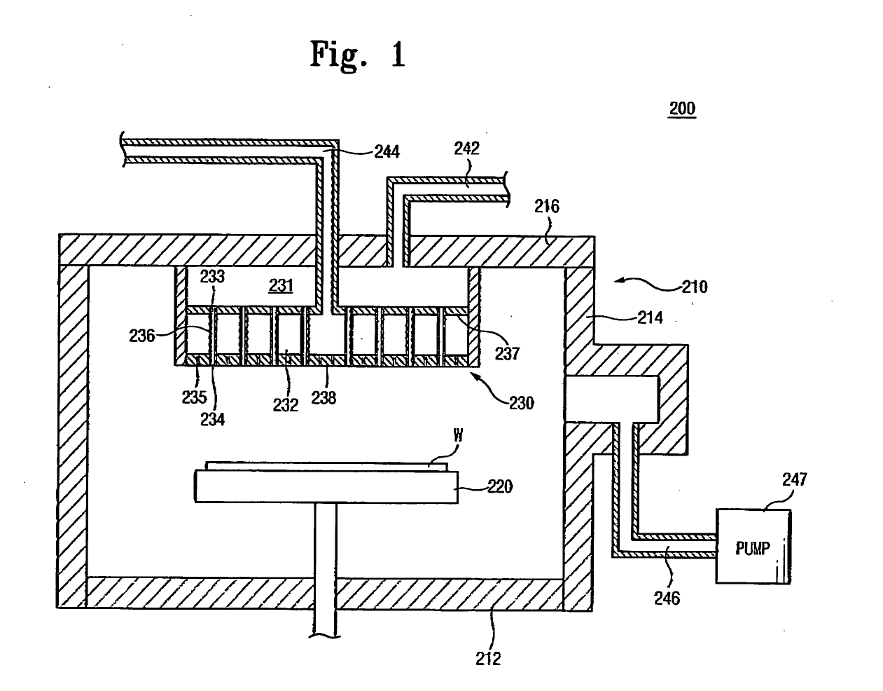

FIG. 1 illustrates a schematic section view of a thin film forming apparatus according to an embodiment of the present invention. Referring to FIG. 1, a thin film deposition apparatus 200 may include a process chamber 210, a susceptor 220, a shower head 230, a first supply pipe 242, a second supply pipe 244, and an outlet pipe 246. The thin film deposition apparatus 200 may include a process chamber 210 defined by a top wall 216, bottom wall 212 and side wall 214.

In this example, the susceptor 220 may support wafer “W” and may be oriented in a lower portion of the process chamber 210. A heater (not shown) may be provided in the chamber 210 to maintain the internal temperature of the process chamber 210 above the decomposition temperature of a reaction gas and to heat the wafer “W” to a temperature high enough to ensure a smooth deposition of the reaction product on the wafer “W”. Generally, since the wafer “W” should be heated above 500° C., the susceptor 220 may be heated to a temperature above 600° C.

The shower head 230 may be installed so that it faces the susceptor 220, and is illustrated at the upper portion of the process chamber 210. The shower head 230 may receive the reaction gas or gases and sprays the reaction gas toward the susceptor and wafer W.

The process chamber 210 may include an exhaust line 246 used to keep the inside of the process chamber 210 at a constant pressure and to exhaust deposition residues. A pump 247 may be connected to the exhaust line 246 to aid in maintaining an optimal environment inside the chamber 210.

The shower head 230 may combine numerous interconnected parts, including a first inflow portion 231 positioned at an upper portion thereof and a second inflow portion 232 positioned at a lower portion thereof. A first injection plate 237 may be positioned between the first inflow portion 231 and the second inflow portion 232 to divide the first inflow portion 231 and the second inflow portion 232, and a second injection plate 238 may be provided under the second inflow portion 232. The space between the first injection plate 237 and the second injection plate defines the second inflow portion 232. A plurality of first holes 233 may be formed in the first injection plate 237 and a corresponding plurality of second holes 234 may be formed in the second injection plate 238. The first holes 233 and the second holes 234 may be at opposite ends of the injection pipes 236 that deliver gas from the first inflow portion 231 toward the susceptor 220. Third holes 235 may be formed in the second injection plate 238 to deliver gas from the second inflow portion 232 toward the susceptor 220.

The first inflow portion 231 may be connected to the first supply pipe 242, and the second inflow portion 232 may be connected to the second supply pipe 244. Source gases for a thin film forming process are directed toward the susceptor 220 in the chamber 210 through the first supply pipe 242 and the second supply pipe 244. Cleaning gas and purging gas for a cleaning process may also be introduced in this manner.

For example, when forming a thin film, the first reaction gas may be introduced into the first inflow portion 231 via the first supply pipe 242 and the second reaction gas may be introduced into the second inflow portion 232 via the second supply pipe 244. The gases may flow through the showerhead 230 plumbing and toward the susceptor 220. In order to form a titanium nitride layer, the first reaction gas may be a titanium source gas and the second reaction gas can be a nitrogen source gas, and vice versa. For this example, the titanium source gas may include TiCl₄, and the nitrogen source gas may include N₂.

The selection of reaction gases supplied to the first supply pipe 242 and the second supply pipe 244 depends on the desired resultant thin film. In addition, the number of required separate supply pipes depends on the number of a necessary discrete reaction gases. For example, if a purge gas and a carrier gas are necessary, additional supply pipes may be provided. Alternatively, the carrier gas may be introduced into the process chamber 210 together with a reaction gas via the same supply pipe. If a large number of reaction gases are required to synthesize the desired thin film, then the internal plumbing of the showerhead 230 will be quite complex, but based on the same principles described above.

Using the thin film deposition apparatus 200 described above, a method for forming a titanium nitride layer will be described in brief. The wafer “W” may be loaded into the process chamber 210. To start, the pressure and the temperature in the process chamber 210 may be adjusted to appropriate values. In this example, the temperature in the process chamber 210 may be maintained at about 600° C. by the heater. A titanium source gas, e.g., TiCl₄ may be supplied to the first supply pipe 242 and a nitrogen source gas, e.g., N₂ is supplied to the second supply pipe 244. The titanium source gas may be supplied along with a carrier gas, e.g., argon (Ar) or hydrogen (H₂) gas. The TiCl₄ and N₂ may be introduced into the process chamber 210 via the shower head 230, and may be thermally decompose and chemically react to form a titanium nitride layer on the wafer

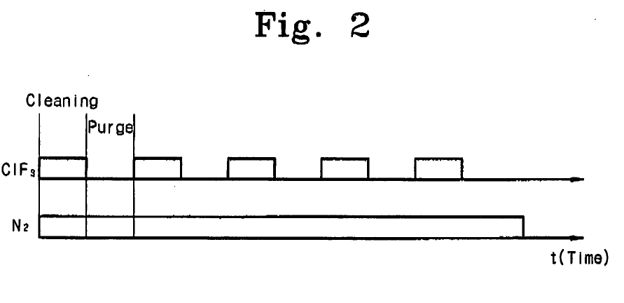

When the titanium nitride layer on the wafer W achieves a targeted thickness, the supply of the source gases may be stopped and the source gases remaining in the process chamber 210 may be exhausted through the outlet pipe 246. However, titanium nitride may have been deposited onto the susceptor 220 and/or the internal surfaces of the chamber 210. If left in place, these deposits could contaminate subsequent batches of wafers W. Next, a method for cleaning the thin film forming apparatus 200 will be described. After formation of the titanium nitride layer is completed, the cleaning process may be performed before the chamber 210 undergoes a significant drop in temperature and without a lengthy delay. The cleaning process is described in more detail with reference to FIG. 2.

FIG. 2 illustrates a schematic diagram of a method for injecting the cleaning gas and the purge gas in the cleaning method according to an embodiment of the present invention.

Referring to FIG. 2, ClF₃ may be used as the cleaning gas for cleaning the process chamber 210. Alternatively, a fluorine-based gas, e.g., F₂, CF₄, C₂F₆, NF₃, and SF₆ may be used as the cleaning gas. However, these gases are provided as examples only and are not intended to limit the present invention. A purge gas may be used to improve the effectiveness of the cleaning process. For example, an inert gas, e.g., N₂gas or Ar gas, may be used as the purge gas. A purge gas may be selected in accordance with gases used for thin film formation. N₂gas may have additional advantages when used for the cleaning process. The purge gas N₂ may be used also as the nitrogen source gas. Therefore, after the titanium nitride layer is formed to a targeted thickness, the cleaning process may be performed without any delay simply by stopping the supply of the titanium source gas, continuing the supply of the N₂gas, and initiating the supply of the cleaning gas ClF₃. That is, the depositing process and the cleaning process can be performed almost continuously. Stopping the supply of the titanium source gas may include stopping the flow of a carrier gas, e.g., argon, if used. Additionally, facility requirements and equipment complexity may be reduced because an additional supply pipe for a dissimilar purge gas is not necessary. An advantage of this method is that a thin film forming process can be performed immediately upon the termination of the cleaning process.

The cleaning gas ClF₃ may be introduced into the process chamber 210 through the first supply pipe 242, the second supply pipe 244 or an additional supply pipe (not shown). The purge gas may be introduced through the first supply pipe 242 or the second supply pipe 244. As described above, when N₂gas is used as the purge gas, it may be desirable that the purge gas is introduced through the second supply pipe 244.

Again referring to FIG. 2, in the cleaning process according to the present embodiment, the cleaning gas may be supplied repeatedly at a short interval and the purge gas may be supplied continuously. That is, while the N₂gas is supplied continuously, the ClF₃ gas may be supplied during a plurality of cleaning periods, separated by a plurality of purge periods. The periodic supply of the ClF₃ gas means that the flow of the ClF₃ gas is repeatedly started and stopped for predetermined time periods. While the supply of the ClF₃ gas is stopped, reaction by-products and a residual etching gas may be exhausted through the outlet pipe 246 by the continuously-flowing purge gas.

It is understood that the contaminative titanium nitride layer left in the process chamber 210 may be removed in accordance with the reaction formulas:

ClF₃→Cl₂+F Reaction formula (1); and

TiN+F→TiF₄+N₂ Reaction formula (2).

Through the reaction formula (1), ClF₃ may be decomposed to generate F, and through the reaction formula (2), the generated F may react with the titanium nitride layer to produce a volatile by-product TiF₄, thereby removing the titanium nitride layer from the susceptor 220 and the internal surfaces of the chamber 210.

In this embodiment, the supply period Ti of the cleaning gas may be sufficient to minimize damage to the inside of the process chamber 210 while providing the desired beneficial cleaning function. The cleaning period and the purge period may be appropriately set within the scope of the present invention.

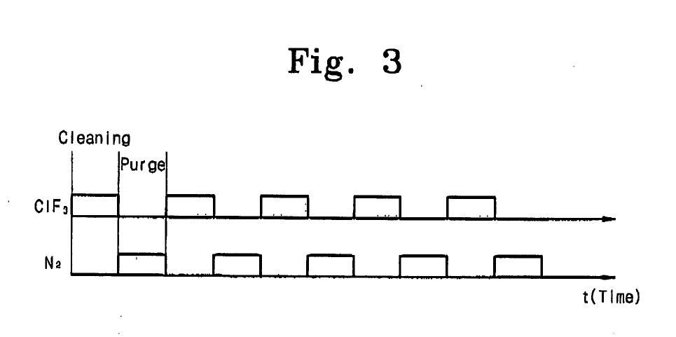

FIG. 3 illustrates a schematic diagram of a method for cleaning the thin film forming apparatus according to another embodiment of the present invention. According to the embodiment, and unlike the above embodiment described with reference to FIG. 2, the purge gas is supplied periodically. That is, in the present embodiment, the cleaning gas ClF₃ may be supplied periodically to a deposition process chamber, and the purge gas may also be supplied periodically. In this embodiment, the ClF₃ gas and the purge gas may be supplied in turn. When the cleaning gas is supplied during the cleaning period, the purge gas is not supplied. When the purge gas is supplied during the purge period, the cleaning gas is not supplied. The purge period for the purge gas may be set equal to, shorter than or longer than the cleaning period for the cleaning gas to maximize the effectiveness of the cleaning process. In other words, the purge period does not have to be equal to the cleaning period.

As described above, the cleaning method of the present invention may reduce damage to the interior wall of the chamber 210 due to the cleaning gas and may start to remove the thin film deposited on the susceptor 220 and interior walls and components of the chamber 210 almost immediately after the thin film deposition process is completed. This process saves time, money, and resources by quickly and effectively cleaning the chamber 210 before it cools, and may clean the chamber 210 in a manner that significantly reduces the possibility of damage due to etching. Further, the non-continuous flow of cleaning gas and/or purge gas reduces the amount of each of these gases required to perform these processes.

Exemplary embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims;

What is claimed is:

1. A method for cleaning a thin film forming apparatus, the method comprising:
supplying a purge gas into a process chamber of the thin film forming apparatus; and
periodically supplying a cleaning gas into the process chamber.

2. The method as claimed in claim 1, wherein the purge gas is supplied periodically such that the purge gas and the cleaning gas are supplied alternately.

3. The method as claimed in claim 1, wherein the temperature of the process chamber is kept at 300° C. or more.

4. The method as claimed in claim 1, wherein the purge gas comprises one of N₂ gas and Ar gas.

5. The method as claimed in claim 1, wherein the process chamber comprises one of a CVD (Chemical Vapor Deposition) chamber, a PVD (Physical Vapor Deposition) chamber, an ALD (Atomic Layer Deposition) chamber, an MOCVD apparatus, a diffusion apparatus, and a furnace.

6. The method as claimed in claim 1, wherein the cleaning gas is a fluorine-based gas.

7. The method as claimed in claim 6, wherein the fluorine-based gas comprises ClF₃, F₂, CF₄, C₂F₆, NF₃, and SF₆.

8. The method as claimed in claim 1, wherein the purge gas is supplied at least while the cleaning gas is not supplied.

9. The method as claimed in claim 8, wherein the cleaning gas comprises ClF₃, F₂, CF₄, C₂F₆, NF₃, and SF₆.

10. A method for forming a thin film using a thin film forming apparatus, the method comprising:
supplying a first reaction gas and a second reaction gas into a process chamber of the thin film forming apparatus to form a thin film;
stopping the supplying of the first reaction gas; and
periodically supplying a cleaning gas into the process chamber.

11. The method as claimed in claim 10, wherein the second reaction gas is supplied periodically after the supplying of the first reaction gas is stopped.

12. The method as claimed in claim 11, wherein the second reaction gas and the cleaning gas are alternately supplied.

13. The method as claimed in claim 10, wherein the first reaction gas is TiCl₄ and the second reaction gas is N₂.

14. The method as claimed in claim 10, wherein the cleaning gas comprises one of ClF₃, F₂, CF₄, C₂F₆, NF₃, and SF₆.

15. The method as claimed in claim 10, further comprising:
supplying the first reaction gas through a first supply pipe of the thin film forming apparatus; and
supplying the second reaction gas through a second supply pipe.

16. The method as claimed in claim 15, wherein the cleaning gas is supplied through the first supply pipe.

17. The method as claimed in claim 10, wherein a purge gas is supplied at least when the cleaning gas is not supplied.

18. The method as claimed in claim 10, further comprising:
when the supplying of the first reaction gas is stopped, stopping the supplying of the second reaction gas; and
supplying a purge gas into the process chamber after the supplying of the first reaction gas and the second reaction gas is stopped.

19. The method as claimed in claim 18, wherein the purge gas and the cleaning gas are alternately supplied.

20. The method as claimed in claim 18, wherein the purge gas is supplied at least when the cleaning gas is not supplied.
